(19) United States
(12) Patent Application Publication
(10) Pub. No.: US 2010/0040534 A1
(43) Pub. Date: Feb. 18, 2010

(54) RADICAL GENERATING APPARATUS AND ZNO-BASED THIN FILM

(75) Inventors: Ken Nakahara, Kyoto (JP); Hiroyuki Yuji, Kyoto (JP); Kentaro Tamura, Kyoto (JP); Shunsuke Akasaka, Kyoto (JP); Masashi Kawasaki, Miyagi (JP); Akira Ohtomo, Miyagi (JP); Atsushi Tsukazaki, Miyagi (JP)

Correspondence Address: RABIN & Berdo, PC, 1101 14TH STREET, NW, SUITE 500, WASHINGTON, DC, 20005, US

(73) Assignee: ROHM Co., LTD., Kyoto-fu (JP)

(21) Appl. No.: 12/450,146

(22) PCT Filed: Mar. 14, 2008
(86) PCT No.: PCT/JP2008/054731

§ 371 Date: Sep. 14, 2009

(30) Foreign Application Priority Data
Mar. 15, 2007 (JP) 2007-067390

(51) Int. Cl. C01G 9/02; C23C 16/513

(52) U.S. Cl. 423/622; 118/723 R

(57) ABSTRACT

Provided are: a radical generating apparatus that increases a purity of emitted plasma atoms, prevents contamination with impurities, and is improved in controllability over ion concentration; and a ZnO-based thin film prevented from being contaminated with impurities. A high-frequency coil (4) is wound around an outer side of a discharging tube (10), and a terminal of the high-frequency coil (4) is connected to a high-frequency power source (9). The discharging tube (10) is constituted by a discharging cylinder (1), a lid (2) and a gas introducing bottom plate (3). Additionally, a support base (8) is provided, a support post (6) is arranged on the support base (8), and a shutter (5) is connected to the support post (6). With respect to shaded components, that is, the shutter (5), the lid (2), the discharging cylinder (1) and the gas introducing bottom plate (3), an entirety or a part thereof is formed of a silicon-based compound such as quartz.

### TECHNICAL FIELD

The present invention relates to: a radical generating apparatus that, in formation of a film of a compound containing an element which is gaseous when uncombined with other elements, brings a gaseous element into a plasma state and supplies the gaseous element; and a ZnO-based thin film.

### BACKGROUND ART

There exist, for example, nitrides, oxides and the like as compounds each containing an element which is gaseous when uncombined with other elements. The oxides, such as superconductive oxides represented by YBCO, transparent conductive materials represented by ITO, and giant magnetic resistance materials represented by (LaSr)MnO₃, have been one of the hottest research fields for having various properties which conventional semiconductors, metals and organic substances can not achieve.

Incidentally, although it is a common practice that, as often with semiconductor devices, a device which develops a unique function can be produced by laminating and etching several thin films having different functions, thin film forming methods for oxides are limited to sputtering, PLD (pulse laser disposition) and the like, by which it is difficult to produce lamination structures as seen in semiconductor devices. This is because the sputtering usually has difficulty in obtaining a crystal thin film, and because the PLD, basically employing point evaporation, has difficulty in obtaining a large area, even a size of 2 inches.

A plasma assisted molecular beam epitaxy (PAMBE) has been practiced as a method by which lamination structures as seen in semiconductor devices can be produced. As one of the oxides attracting a lot of attention in studies using this molecular beam epitaxy method, there exists ZnO.

ZnO has been slow in growing as a semiconductor device material although the multifunctionality, its high potential of light emission potential and the like thereof have been attracting attention. That is because the largest drawback thereof is that, since subjecting ZnO to acceptor doping has been difficult, p-type ZnO has been unobtainable.

In recent years, however, studies thereon have become very active under a situation where, as seen in Non-patent Documents 1 and 2, technological advancement has made p-type ZnO obtainable and also has achieved light emission thereof.

A radical generating apparatus is used as an apparatus that supplies a gaseous element when oxygen, which is a gaseous element, is supplied in a case of fabricating a ZnO thin film, or when the doping with nitrogen, which is a gaseous element, is performed for the purpose of obtaining p-type ZnO, as described above (for example, refer to Patent Document 1).

As shown in FIG. 6, the radical generating apparatus includes: a hollow discharging chamber 11; a high-frequency coil (an RF coil) 14 wound around an outer side of the discharging chamber 11; a lid 12 provided to the exit side of the discharging chamber 11; a gas introducing bottom plate 13 provided to the entrance side of the discharging chamber 11; a gas supplying tube 17 connected to the gas introducing bottom plate 13; a support base 18; a support post 16; a shutter 15; a high-frequency power source 19; and the like.

Additionally, to the gas supplying tube 17, for example, a nitrogen source such as a liquid nitrogen tank is connected in a case requiring a nitrogen element, or an oxygen source such as a liquid oxygen tank is connected in a case requiring an oxygen element. A gaseous element is supplied to the discharging chamber 11 from the gas supplying tube 17. Plasma atoms are generated with a high frequency wave being applied to the gaseous element by the high-frequency coil 14. The plasma atoms are released from an emission hole provided in the lid 12. These plasma atoms are used for formation of a ZnO thin film or for doping with a p-type impurity.

Patent Document 1: JP-A-7-14765

Non-patent Document 1: A. Tsukazaki et al., JJAP 44 (2005) L643

Non-patent Document 2: A. Tsukazaki et al., Nature Material 4 (2005) 42

### DISCLOSURE OF THE INVENTION

### Problems to be Solved by the Invention

However, since the plasma atoms are high-energy particles, a sputtering phenomenon is caused by the plasma atoms, atoms composing the discharging chamber 11, the lid 12, the gas introducing bottom plate 13 and the like are pushed out to be mixed among the plasma atoms, which not only makes a high-purity gaseous element unobtainable but also forms a contamination source, whereby there has been not only a problem that obtaining desired composition and doping is difficult but also a problem that introduction of an unintended impurity makes controllability over ion concentrations difficult.

The present invention was invented in order to solve the above described problems, and an object of the present invention is to provide: a radical generating apparatus that increases a purity of emitted radical atoms, prevents contamination with impurities, and is improved in controllability over ion concentration; and a ZnO-based thin film prevented from being contaminated with impurities.

### Means for Solving the Problems

In order to achieve the above-mentioned object, an invention according to claim 1 is a radical generating apparatus, which generates plasma by introducing a gas into a discharging tube, characterized in that at least a part of a wall face, with which the gas comes into contact, of the discharging tube is formed of a silicon-based compound.

Additionally, an invention according to claim 2 is the radical generating apparatus according to claim 1, characterized in that an entirety of the wall face, with which the gas comes into contact, of the discharging tube is formed of a silicon-based compound.

Additionally, an invention according to claim 3 is the radical generating apparatus according to any one of claims 1 and 2, characterized in that a shutter provided to the plasma emission side of the discharging tube is formed of a silicon-based compound.

Additionally, an invention according to claim 4 is the radical generating apparatus according to any one of claims 1 to 3, characterized in that the silicon-based compound is composed of quartz.

Additionally, an invention according to claim 5 is the radical generating apparatus according to claim 4, characterized in that a content of a III-group element in the quartz is not more than 1 ppm.

Additionally, an invention according to claim 6 is the radical generating apparatus according to claim 5, characterized in that the III-group element is Al.

Additionally, an invention according to claim 7 is the radical generating apparatus according to any one of claims 1 to 6, characterized in that, as to the III-group element, the gas introduced into the discharging tube is nitrogen or a nitrogen oxide.

Additionally, an invention according to claim 8 is a ZnO-based thin film characterized in that a boron concentration in the film is not more than 1×10¹⁶cm⁻³.

Additionally, an invention according to claim 9 is a ZnO-based thin film characterized in that an Al concentration in the film is not more than 1×10¹⁶ cm⁻³.

### Effects of the Invention

In the radical generating apparatus according to the present invention, at least a part of a wall face, on which a gas that serves as a source of plasma atoms and is introduced into the discharging tube comes into contact with the discharging tube, is formed of a silicon-based compound. Accordingly, the radical generating apparatus according to the present invention can, as compared to conventional one, involve only a very small amount of impurities pushed out, by sputtering, from inside the discharging tube, increase a purity of plasma atoms, and control contamination. Additionally, by having an entirety of the discharging tube wall face, with which a supplied gas comes into contact, formed of a silicon-based compound, a purity of plasma atoms can be further increased. Additionally, a less contaminated ZnO-based thin film can be fabricated by increasing a purity of plasma atoms.

### BRIEF DESCRIPTION OF THE DRAWINGS

FIG. 1 is a view showing a structure of a radical generating apparatus of the present invention.

FIG. 2 is a chart showing impurity concentrations in a ZnO film in a case using the radical generating apparatus of the present invention.

FIG. 3 is a chart showing impurity concentrations in a ZnO film in a case using a conventional radical generating apparatus.

FIG. 4 is a chart showing impurity concentrations in a ZnO film in a case using, as a constituent material of the radical generating apparatus of the present invention, quartz containing a small amount of impurities.

FIG. 5 is a chart showing impurity concentrations in a ZnO film in a case using, as a constituent material of the radical generating apparatus of the present invention, quartz containing a large amount of impurities.

FIG. 6 is a view showing a structure of a generally used radical generating apparatus.

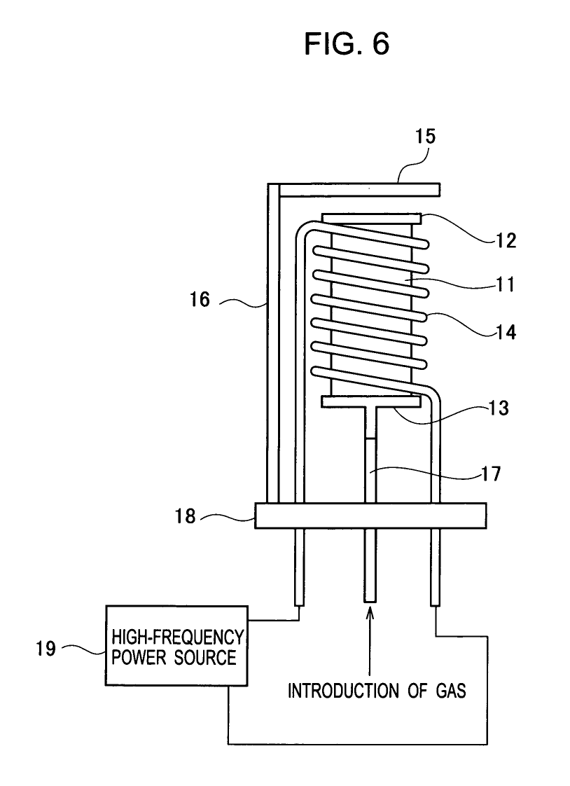

### DESCRIPTION OF REFERENCE NUMERALS

1 discharging cylinder
2 lid
3 gas introducing bottom plate
4 high-frequency coil
5 shutter
6 support post
7 gas supplying tube
8 support base
9 high-frequency power source
10 discharging tube

### BEST MODE FOR CARRYING OUT THE INVENTION

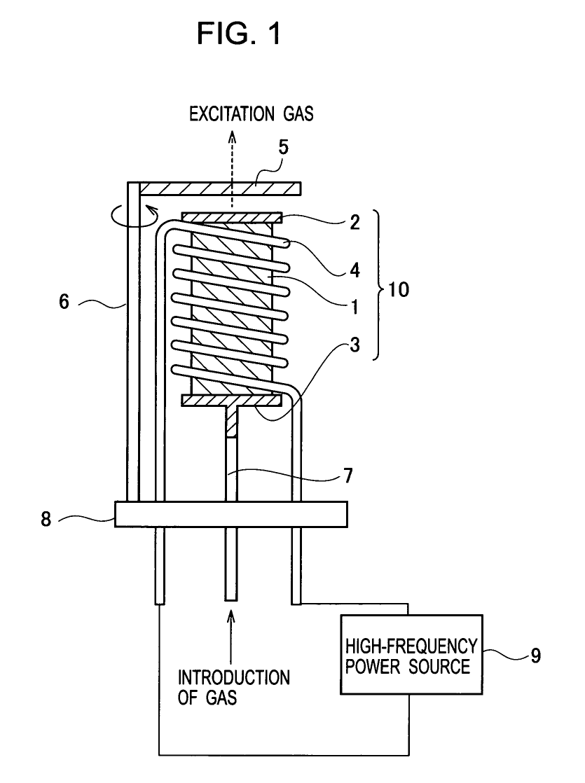

One embodiment of the present invention will be described below with reference to the drawings. FIG. 1 shows a schematic structure of a radical generating apparatus of the present invention.

A high-frequency coil 4 is wound around an outer side of a discharging tube 10, and a terminal of the high-frequency coil 4 is connected to a high-frequency power source 9. The discharging tube 10 is constituted by a discharging cylinder 1, a lid 2 and a gas introducing bottom plate 3. Additionally, a support base 8 is provided, a rotatable support post 6 is arranged on the support base 8, and a shutter 5 is connected to the rotatable support post 6.

The gas introducing bottom plate 3 is connected to the gas supplying tube 7 on a lower side, and introduces into a discharging cylinder 1 a gas supplied to the gas supplying tube 7. The discharging cylinder 1 has a hollow structure, and a high frequency voltage (electric filed) is applied to the introduced gas by the high-frequency coil 4, whereby a plasma state is formed. An emission hole (unillustrated) is provided in the lid 2, and plasma generated in the discharging cylinder 1 is emitted from this emission hole.

The shutter 5 is configured to block and open an upper part of the emission hole bored in the lid 2 by rotation of the support post 6, and, in a case not requiring supply of plasma atoms, the shutter 5 is put in a position blocking an upper side of the emission hole bored in the lid 2 of the shutter 5. On the other hand, when thin film formation, doping of a p-type impurity or the like is performed, the support post 6 rotates to move the shutter 5, and opens the upper part of the emission hole bored in the lid 2, thereby introducing into a growth chamber the plasma atoms (an excitation gas in the drawing) emitted from the discharging tube 10.

Here, with respect to shaded components, that is, the shutter 5, the lid 2, the discharging cylinder 1 and the gas introducing bottom plate 3, an entirety or a part thereof are formed of a silicon-based compound in the present invention. In particular, with respect to the lid 2, the discharging cylinder 1 and the gas introducing bottom plate 3 which constitute the discharging tube 10, at least wall faces thereof with which a raw material gas comes into direct contact are configured to be composed of a silicon-based compound because the raw material gas passes through the insides thereof, and also because plasma atoms when a plasma state has been formed come into contact with the wall faces of the respective components. In the above description, in a case having a wall face of a part of each of the components, which are the lid 2, the discharging cylinder 1 and the gas introducing bottom plate 3, formed of a silicon-based compound, meanings of having a part formed of a silicon-based compound include: having, for example, a part of an inner wall face of the discharging cylinder 1 composed of a silicon-based compound; and employing a dual structure where, while only the inner wall face of the discharging cylinder 1 is composed of a silicon-based compound, an outer side thereof is formed of another material.

Additionally, SiO₂, SiN, SiON or the like may be used as the silicon-based compound, and it is SiO₂ that is the most stable and thereby desirable. Note that, although the lid 2, the discharging cylinder 1 and the gas introducing bottom plate 3, which constitutes the discharging tube 10, are described as separate components in FIG. 1, a part or an entirety thereof may be integrated by being fused.

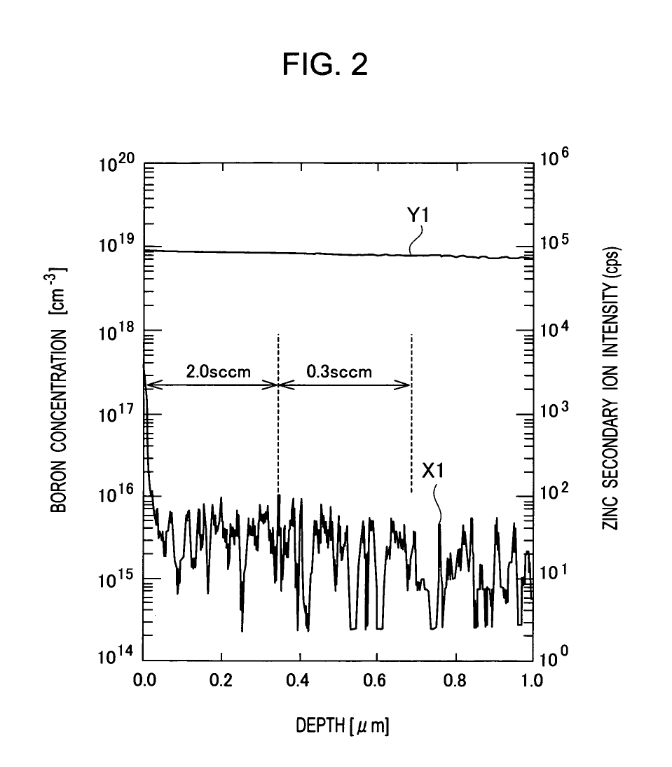

FIG. 2 shows B (boron) concentrations in a nitrogen-doped ZnO film in a case where the radical generating apparatus of the present invention was used for generating nitrogen radicals, specifically, a case where an entirety of the discharging tube 10, and the shutter 5 were composed of quartz (a major component of which is SiO₂). Y1 indicates Zn (zinc) secondary ion intensities in the nitrogen-doped ZnO film; X1 indicates boron concentrations in the nitrogen-doped ZnO film; and a horizontal axis indicates depths (film thickness).

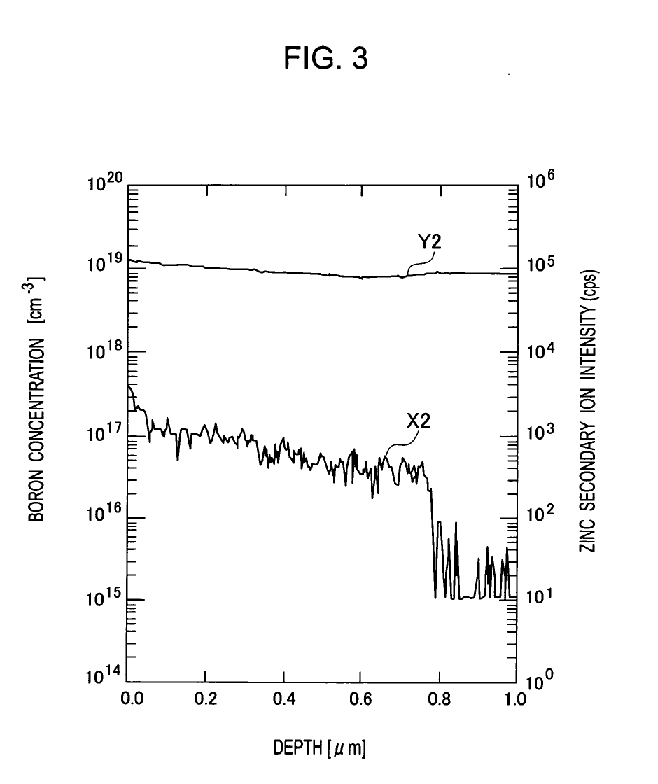

As is seen from this drawing, the concentrations of boron, which was an impurity in the nitrogen-doped ZnO film, took small values at all depths. Additionally, it can be seen that, while being in a radical condition that a flux of a raw material gas was changed to 0.3 sccm and to 2 sccm along the way with a power of the high frequency power source being set to 300 W, the impurity boron concentrations did not increase even though the flux of the raw material gas increased. The concentrations of boron, which was an impurity in the nitrogen-doped ZnO film, were only remaining at about background level as can be seen also by comparison thereof with FIG. 3 described later, and, with respect to the levels, it can be found that the boron concentrations in the film can be formed into not more than 1×10¹⁶ cm⁻³ as shown in FIG. 2.

On the other hand, in a case where an entirety of the discharging tube 10, and the shutter 5 were made of PBN (boron nitride) as in a conventional structure, concentrations of B (boron) existing in a nitrogen-doped ZnO film are shown in FIG. 3. Y2 indicates Zn (zinc) secondary ion intensities in the nitrogen-doped ZnO film; X2 indicates boron concentrations in the nitrogen-doped ZnO film; and a horizontal axis indicates depths (film thickness) as in the case of FIG. 2.

A radical condition was that, while a power of the high frequency power source was set to 400 W, a flux of a raw material gas was set to 0.1 sccm. The concentrations of boron, which was an impurity in the nitrogen-doped ZnO film, took larger values even with a flux of a raw material gas being smaller than that of FIG. 2, whereby it can be seen that a configuration of the present invention in which a material of the discharging tube and the shutter was made of quartz showed decreases in B concentration to values being at least one digit smaller than those of the conventional one made of PBN, and thus showed very sharp decreases in impurity in the film as compared to the conventional one. This is because, in the case where the entirety of the discharging tube, and the shutter were made of PBN (boron nitride) as in a conventional structure, the boron concentrations became higher as boron atoms in PBN that was a component material were pushed out by plasma particles. While nitrogen serves as an acceptor in a ZnO film and contributes to p-type conduction, boron serves as a donor and impedes p-type conduction. Therefore, contamination with boron, which becomes an impediment to p-type conduction, requires to be inhibited as far as possible. In this respect, the radical generating apparatus of the present invention was able to inhibit contamination with boron.

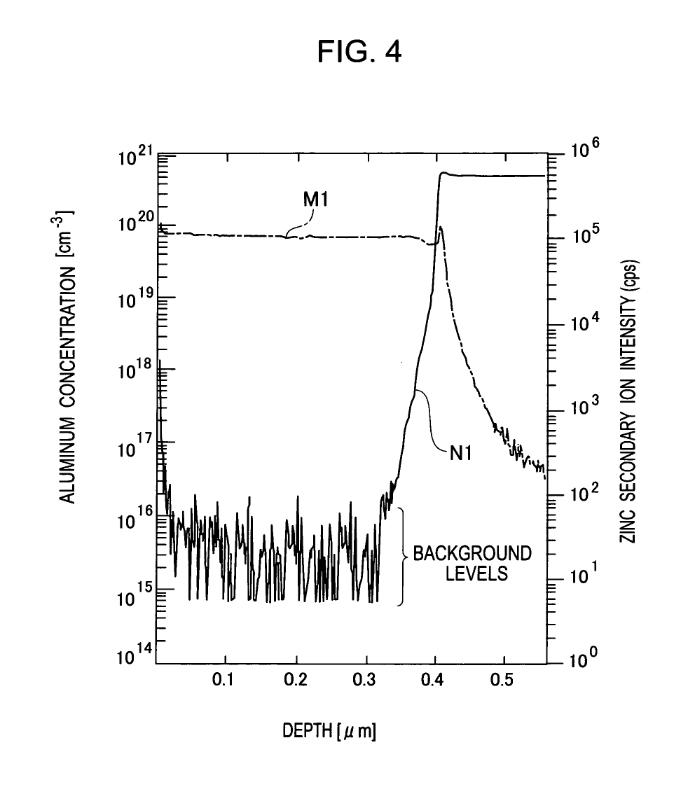

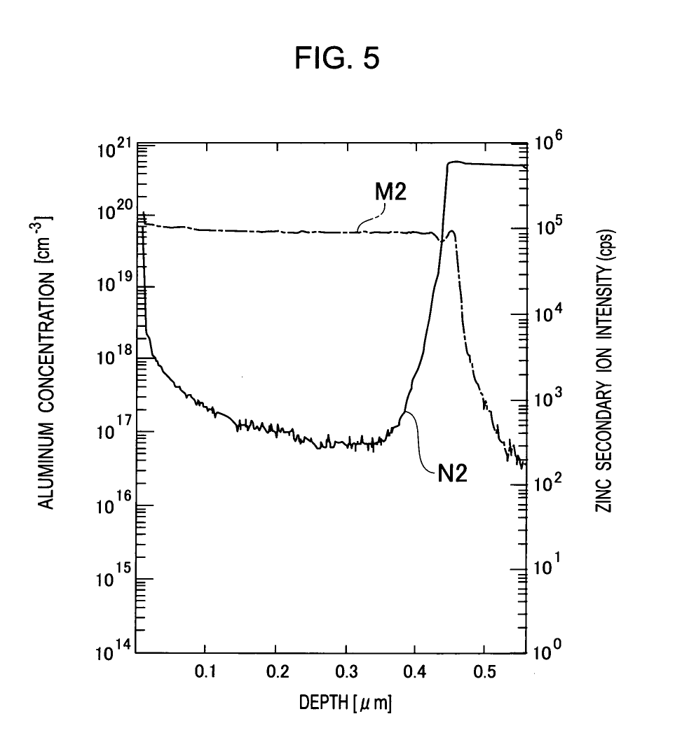

On the other hand, purities of quartz in use massively influence impurity concentrations in a film, and data thereon are shown in FIGS. 4 and 5. While being mainly composed of SiO₂, quartz is contaminated with a small amount of impurities in many cases. In FIG. 4, in a case where an Al concentration contained in quartz was not more than 1 ppm, N1 indicates Al concentrations in a ZnO film and M1 indicates zinc secondary ion intensities in the ZnO film. In FIG. 5, in a case where an Al concentration contained in quartz was more than 1 ppm, N2 indicates Al concentrations in a ZnO film and M2 indicate zinc secondary ion intensities in the ZnO film. In each of FIGS. 4 and 5, a region having shown a sharp decrease in zinc secondary ion intensity in the ZnO film corresponds to a sapphire substrate provided as a growth substrate.

In FIG. 4, that is, in the case where an Al concentration contained in quartz was not more than 1 ppm, it can be found that an average of the Al concentrations in the ZnO film decreased to background levels of a measurement apparatus. On the other hand, in the case of FIG. 5 where an Al concentration contained in quartz was 5 ppm exceeding 1 ppm, an average of the Al concentrations in the ZnO film increased even to 1.47×10¹⁷ cm⁻³. Since an impurity concentration relative to nitrogen radicals thus shows a sharp increase when an Al concentration contained in quartz exceeds 1 ppm, it is desirable that an Al concentration contained in quartz be not more than 1 ppm. Additionally, if an Al concentration contained in quartz is set to not more than 1 ppm, a ZnO film can be formed in a way that Al concentrations in the ZnO film is not more than 1×10¹⁶ cm⁻³ as can be seen from background levels shown in FIG. 4.

As has been described above, a less contaminated gaseous element essential for forming a high-purity and high-quality thin film can be supplied according to the radical generating apparatus of the present invention.

By use of the radical generating apparatus of the present invention, a formation method of a ZnO-based thin film sensitive to contamination will be briefly described. As the growth method of a ZnO-based thin film, a ZnO substrate is put in a load lock chamber, and is heated for about 30 minutes at 200° C. in a vacuum environment of about 1×10⁻⁵ to 1×10⁻⁶ Torr for moisture removal. Then, after passing through a transportation chamber having vacuum of about 1×10⁻⁹ Torr, the substrate is introduced into a growth chamber having a wall face having been cooled with liquid nitrogen, and a ZnO-based thin film is grown by use of an MBE method.

By use of a Knudsen cell in which high-purity Zn of 7 N has been set in a crucible made of PNB, Zn is supplied in the form of a Zn molecular beam by being heated to about 260 to 280° C. and sublimated. While there exists Mg as one example of the IIA group elements, Mg is supplied also in the form of a Mg molecular beam by use of high-purity Mg of 6 N and by being heated to about 300 to 400° C. and sublimated from a cell of the same structure.

Oxygen is supplied as an oxygen source by use of O₂ gas of 6 N after: plasma is generated with this O₂ gas being supplied at about 0.1 sccm to 5 sccm to a radical generating apparatus through a stainless steel tube having an electrolytically polished inner face and with RF high frequency waves of about 100 to 300 W being applied thereto, the radical generating apparatus having a small emission orifice formed in a cylinder and being provided with a discharging tube composed of quartz; and the O₂ gas is thereby brought into an oxygen radical state where reaction activity is heightened. Plasma is essential, and no ZnO-based film is formed only with a raw gas of O₂ being introduced.

A case where the ZnO-based film fabricated by the above method is subjected to nitrogen doping will be considered. Nitrogen is supplied as a nitrogen source by use of a gas of pure N2 or a nitrogen oxide after: plasma is generated with this gas being supplied at about 0.1 sccm to 5 sccm to the radical generating apparatus, which is the same as above one used for oxygen, and with RF high frequency waves of about 50 W to 500 W being applied thereto; and the gas is thereby brought into a nitrogen radical state where reaction activity is heightened. Thereby, nitrogen doping is performed to obtain a p-type thin film. Note that, in a case using a nitrogen oxide in the doping, the nitrogen oxide may be used singly since a nitrogen-doped ZnO-based film can be fabricated without oxygen radicals being supplied and singly with the nitrogen oxide.

1. A radical generating apparatus, which generates plasma by introducing a gas into a discharging tube, characterized in that at least a part of a wall face, with which the gas comes into contact, of the discharging tube is formed of a silicon-based compound.

2. The radical generating apparatus according to claim 1, characterized in that an entirety of the wall face, with which the gas comes into contact, of the discharging tube is formed of a silicon-based compound.

3. The radical generating apparatus according to claim 1, characterized in that a shutter provided to the plasma emission side of the discharging tube is formed of a silicon-based compound.

4. The radical generating apparatus according to claim 1, characterized in that the silicon-based compound is composed of quartz.

5. The radical generating apparatus according to claim 4, characterized in that a content of a III-group element in the quartz is not more than 1 ppm.

6. The radical generating apparatus according to claim 5, characterized in that the III-group element is Al.

7. The radical generating apparatus according to claim 6, characterized in that the gas introduced into the discharging tube is nitrogen or a nitrogen oxide.

8. A ZnO-based thin film characterized in that a boron concentration in the film is not more than 1×10¹⁶ cm−3.

9. A ZnO-based thin film characterized in that an Al concentration in the film is not more than 1×10¹⁶ cm−3.

10. The radical generating apparatus according to claim 5, characterized in that the gas introduced into the discharging tube is nitrogen or a nitrogen oxide.

11. The radical generating apparatus according to claim 4, characterized in that the gas introduced into the discharging tube is nitrogen or a nitrogen oxide.

12. The radical generating apparatus according to claim 3, characterized in that the gas introduced into the discharging tube is nitrogen or a nitrogen oxide.

13. The radical generating apparatus according to claim 2, characterized in that the gas introduced into the discharging tube is nitrogen or a nitrogen oxide.

14. The radical generating apparatus according to claim 1, characterized in that the gas introduced into the discharging tube is nitrogen or a nitrogen oxide.
